(19) United States
(12) Patent Application Publication
(10) Pub. No.: US 2015/0252472 A1
(43) Pub. Date: Sep. 10, 2015

(54) METHOD AND VACUUM SYSTEM FOR REMOVING METALLIC BY-PRODUCTS

(71) Applicant: CLEAN FACTORS CO., LTD., Hwaseong-si, Gyeonggi-do (KR)

(72) Inventors: Gyoung O Ko, Seoul (KR); Myung keun Noh, Seongnam-si (KR)

(73) Assignee: CLEAN FACTORS CO., LTD., HWASEONG-SI, (KR)

(21) Appl. No.: 14/432,487

(22) PCT Filed: Oct. 16, 2013
(86) PCT No.: PCT/KR2013/009267

§ 371 Date: Mar. 31, 2015

(30) Foreign Application Priority Data
Oct. 17, 2012 (KR) 10-2012-0115225

(51) Int. Cl. C23C 16/44; C23C 16/06

(52) U.S. Cl. CPC C23C 16/4412; C23C 16/06

(57) ABSTRACT

Provided is a method for removing metallic by-products. The method includes depositing a metal precursor to form a metal layer in a process chamber, plasma treating an exhaust gas containing the residual metal precursor transferred from the process chamber, treating metallic by-products generated by the plasma treatment with an oxidizing gas to produce metal oxides, and discharging the metal oxides by pumping.

### TECHNICAL FIELD

The present disclosure relates to a method and vacuum system for removing metallic by-products.

### BACKGROUND ART

Various raw materials are introduced into reduced pressure process chambers for the manufacture of semiconductors and displays. Diverse processes, such as ashing, deposition, etching, photolithography, cleaning, and nitriding treatment, are carried out in the process chambers. Various kinds of volatile organic compounds, acids, malodorous gases, ignitable substances, and substances restricted by environmental legislation are contained in exhaust gases from the process chambers. A conventional semiconductor manufacturing system includes a vacuum pump for evacuating process chambers and a scrubber installed downstream of the vacuum pump to purify exhaust gases containing pollutants from the process chambers and release the purified gases into the atmosphere.

However, unreacted raw materials and process by-products may enter and be deposited in the form of solids in the vacuum pump during pumping. The solid by-products may shorten the operating life of the vacuum pump. In view of this situation, a plasma reactor or a trap is installed upstream of the vacuum pump to decompose the pollutants so that the pollutants are prevented from entering the vacuum pump.

The plasma reactor installed upstream of the vacuum pump efficiently decomposes the pollutants and by-products with less energy. Particularly, the plasma reactor can control over the particle sizes of the by-products, which improves the flowability of solid-state by-products entering the vacuum pump so that the amount of the by-products accumulated in the vacuum pump can be reduced, contributing to an extension in the life of the vacuum pump.

However, when a metal precursor as a raw material is deposited to form a metal layer in a process chamber, the metal precursor may not be applied to a wafer and may remain unreacted. The unreacted precursor together with metallic by-products may enter a vacuum exhaust system in the course of purging the unreacted raw material from the chamber space. The unreacted precursor and the metallic by-products entering the vacuum exhaust system are coated on the inner parts (e.g., a vacuum exhaust pipe, a vacuum valve, and a vacuum pump) of a vacuum exhaust system to form metal films. The metal films are very firmly attached to the surfaces of the parts and are thus difficult to remove, causing failure of the vacuum valve and operational failure of the vacuum pump, where the rotator-rotator clearance and rotator-housing clearance are at intervals of tens of micrometers. Further, when a plasma reactor is operated to decompose the residual metal precursor, the metallic by-products are coated between both electrodes of the plasma reactor, causing electrical shorting between the electrodes. As a result, plasma cannot be maintained any longer.

### DETAILED DESCRIPTION OF THE INVENTION

According to one aspect of the present invention, a method for removing metallic by-products is provided which includes depositing a metal precursor to form a metal layer in a process chamber, plasma treating an exhaust gas containing the residual metal precursor transferred from the process chamber, treating metallic by-products generated by the plasma treatment with an oxidizing gas to produce metal oxides, and discharging the metal oxides by pumping.

According to a further aspect of the present invention, a vacuum system for removing metallic by-products is provided which includes a process chamber where a metal precursor as a raw material is received and deposited, a vacuum pump for evacuating the process chamber and pumping an exhaust gas containing the metal precursor remaining unreacted in the process chamber, a plasma reactor positioned between the process chamber and the vacuum pump to decompose the residual metal precursor, and a supply unit for supplying an oxidizing gas to the plasma reactor to produce metal oxides.

### BRIEF DESCRIPTION OF THE DRAWINGS

FIG. 1 is a flowchart illustrating a method for removing metallic by-products according to one embodiment of the present invention.

FIG. 2 is a block diagram illustrating the overall configuration of a vacuum system according to one embodiment of the present invention.

FIG. 3 is a block diagram illustrating the configuration of a vacuum system according to one embodiment of the present invention.

FIG. 4 is a block diagram illustrating the configuration of a vacuum system according to a further embodiment of the present invention.

FIG. 5 shows photographs of hot trap baffles after residual metal precursors were captured with hot traps instead of a plasma reactor.

FIG. 6 shows photographs of a disassembled vacuum pump after a residual metal precursor was captured with a hot trap.

FIG. 7 shows (a) a photograph of a room temperature reaction trap and (b) photographs of trap baffles after oxygen was fed into a plasma reactor to convert a residual organic metal precursor to a metal oxide, which was then captured with the room temperature reaction trap.

FIG. 8 shows photographs of a disassembled vacuum pump after a residual metal precursor was converted to a metal oxide, which was then captured with a room temperature reaction trap.

FIG. 9 shows photographs demonstrating the ease of removal of a metal oxide powder coated inside a vacuum exhaust system.

| | |
|---|---|
| 100: Vacuum system | 200: Process system |
| 300: Vacuum exhaust system | 310: Plasma reactor |
| 320: Oxidizing gas supply unit | 330: Vacuum pump |
| 350: Trap | 400: Exhaust system |
| 410: Scrubber | |

### MODE FOR CARRYING OUT THE INVENTION

Various embodiments of the present invention will now be described in detail with reference to the accompanying drawings.

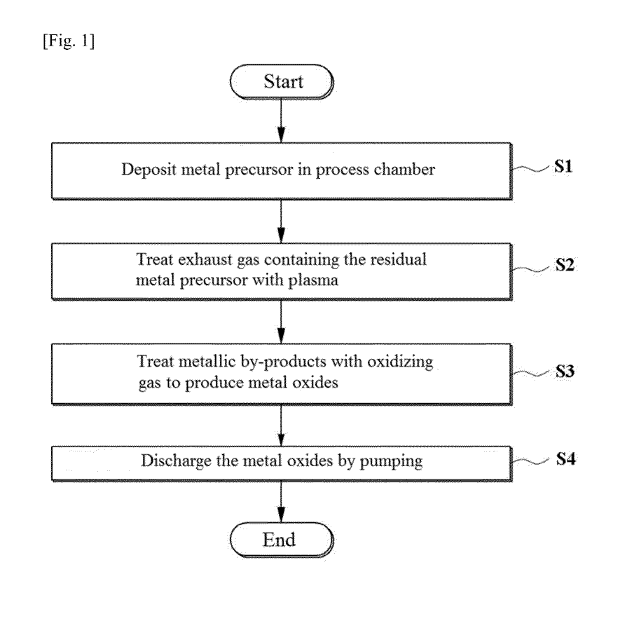

FIG. 1 is a flowchart illustrating a method for removing metallic by-products according to one embodiment of the present invention. Referring to FIG. 1, in step S1, a metal precursor is deposited to form a metal layer in a process chamber. The metal precursor can be deposited by various processes, such as physical vapor deposition (PVD), chemical vapor deposition (CVD), and atomic layer deposition (ALD). If desired, the metal precursor may be vaporized in the presence of an inert carrier gas, such as nitrogen or argon. Additionally, the inert carrier gas may be used during purging in an ALD process.

The metal precursor used in the deposition process is a compound in which ligands are coordinated to a metal. The metal is selected from the group consisting of, but not limited to, Al, Cu, Ni, W, Zr, Ti, Si, Hf, La, Ta, Mg, and combinations thereof. The metal precursor may be selected from the group consisting of, but not limited to, chlorides, hydroxides, oxyhydroxides, alkoxides, amides, nitrates, carbonates, acetates, oxalates, and citrates of the metal, which may be used alone or in combination.

For example, when the metal is Zr, the metal precursor may be Zr(i-OPr)₄, Zr(TMHD)(i-OPr)₃, Zr(TMHD)₂(i-OPr)₂, Zr(TMHD)₄, Zr(DMAE)₄ or tetrakis(ethylmethylamino)zirconium (TEMA-Zr) (where TMHD, DMAE, DEPD, and DMPD represent tetramethylheptanedionate, dimethylaminoethoxide, diethylpentanediol, and dimethylpentanediol, respectively). When the metal is Hf, the metal precursor may be Hf([N(CH₃)(C₂H₅)]₃[OC(CH₃)₃]) or tetrakis(ethylmethylamino)hafnium (TEMA-Hf). When the metal is Al, the metal precursor may be triisobutylaluminum (TIBA), dimethylaluminum hydride (DMAH) or dimethylethylamine alane (DMEAA).

In step S2, an exhaust gas containing the residual metal precursor transferred from the process chamber are decomposed by plasma treatment. The exhaust gas contains process by-products as well as the unreacted precursor. The unreacted precursor and the process by-products are decomposed by plasma treatment. The metal precursor is decomposed or activated by high energy of the plasma. As a result, metallic by-products are generated. Plasma may be created in a plasma reactor using DC, AC, RF or microwaves as energy source. When the installation and maintenance costs of the plasma reactor are taken into consideration, the plasma via dielectric barrier discharge created using an AC power is preferable. The process by-products may be pretreated with reduced pressure (vacuum) plasma rather than by heating. This plasma pretreatment is advantageous in terms of energy saving. The process by-products may be pretreated using a hot trap. In this case, however, the hot trap should be operated at all times to maintain a constant temperature. In contrast, when a plasma apparatus is used to pretreat the process by-products, the plasma on/off can be correlated to the process steps of the tool, so that it can operate only necessary step. Plasma is advantageous in maximizing energy utilization because it has superior energy transfer characteristics to the free molecules over broader space and wide pressure range.

In step S3, metallic by-products generated in the plasma treatment step are treated with an oxidizing gas to convert to metal oxides.

The metal active species may be coated on the surfaces of pipes, vacuum valves, vacuum pumps, etc. to form hard metal films, unlike other process by-products. The formation of metal films on the inner wall of the plasma reactor may cause electrical shorting between electrodes. When the metal active species are treated with the oxidizing gas containing oxygen atoms to produce metal oxides, they are easily detached from the surface of the vacuum exhaust system and are thus easy to remove although the metal oxides are coated on the vacuum exhaust system. Examples of suitable oxidizing gases include air, oxygen, water vapor, ozone, nitrogen oxides (e.g., nitrogen monoxide), hydrogen peroxide, and alcohols (e.g., isopropanol). These oxidizing gases may be used alone or in combination thereof.

In step S4, the metal oxides are discharged by pumping. Since the metal oxides are highly flowable, unlike metals, the exhaust gas containing the metal oxides can be released through an exhaust pipe provided downstream of a vacuum pump by pumping using the vacuum pump.

Preferably, the final release of the exhaust gas is done through the exhaust pipe after it is purified in a scrubber located at the downstream of the vacuum pump.

The method may further include removing the metal oxides with a trap to both minimize introduction of the metal oxides into the vacuum pump and discharge of the metal oxides to the external environment. For example, the method may further include capturing the metal oxides with a trap between steps S3 and S4 or after the pumping step S4.

The use of the method according to the present invention can prevent the vacuum exhaust system from being contaminated by the metal active species derived from the organic metal precursor remaining unreacted after the deposition. This can extend the life of the vacuum exhaust system.

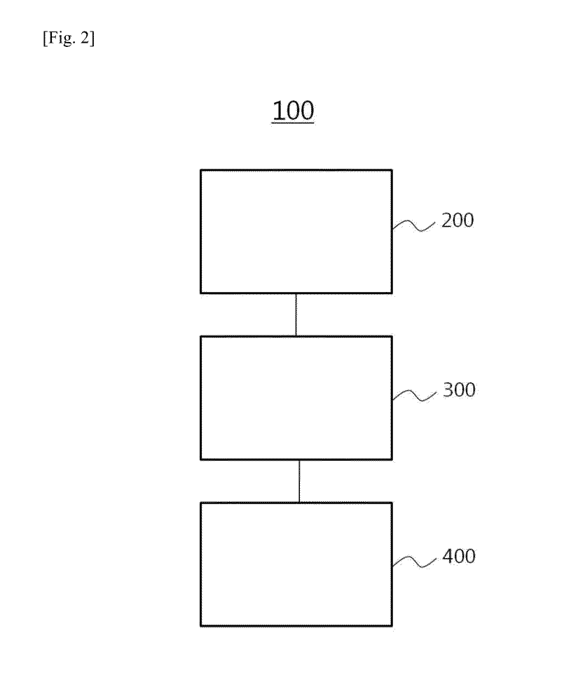

FIG. 2 is a block diagram illustrating the overall configuration of a vacuum system according to one embodiment of the present invention. Referring to FIG. 2, the vacuum system 100 includes a process system 200, a vacuum exhaust system 300, and an exhaust system 400 as a whole.

The process system 200 includes reduced pressure process chambers where various processes necessary for the fabrication of semiconductors, display panels, solar cells or the like are carried out and raw materials including a metal precursor are received from corresponding raw material supply units. The exhaust system 400 includes a scrubber for exhaust gas purification and an exhaust pipe.

The vacuum exhaust system 300 is positioned between the process system 200 and the exhaust system 400 to evacuate the process chambers of the process system 200. Exhaust gases including unreacted precursor and process by-products from the process chambers are transferred to the exhaust system 400 through the vacuum exhaust system 300.

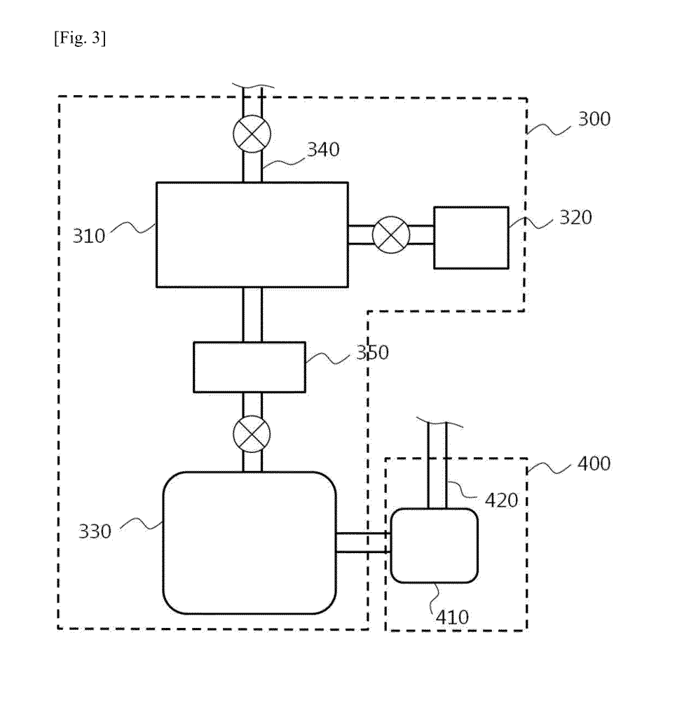

FIG. 3 is a block diagram illustrating the configuration of a vacuum system according to one embodiment of the present invention.

The vacuum exhaust system 300 includes a plasma reactor 310, an oxidizing gas supply unit 320, and a vacuum pump 330.

The plasma reactor 310 is installed upstream of the vacuum pump 330 to generate low-pressure plasma. The energy of the plasma is used to decompose unreacted precursor and process by-products contained in exhaust gases released from the process chambers (not illustrated).

There is no particular restriction on the structure of the plasma reactor 310 for generating low-pressure plasma. The structure of the plasma reactor 310 may vary depending on how plasma is generated. The plasma reactor 310 may generate plasma by various methods. For example, the plasma reactor 310 may be driven by applying a radio frequency (RF) to both ends of a coiled electrode or applying a driving voltage having an alternating current (AC) frequency to a dielectric material and a ring electrode structure to generate a dielectric barrier discharge. The former method necessitates an expensive RF power supply and requires high power consumption. In contrast, the latter method has the advantages of low installation and maintenance costs and high pollutant treatment efficiency. Another advantage of the latter method is that plasma is highly stable against pressure variations during processing, enabling stable long-term operation. Korean Patent No. 10-1065013 discloses a plasma reactor for generating a dielectric barrier discharge by the application of an AC driving voltage.

The plasma reactor 310 takes the form of a pipeline, which is advantageous in that the conductance of the exhaust gas flow can be maintained constant, and as a result, deterioration of vacuum pumping performance can be minimized. The pipeline has a cylindrical tubular shape. Due to this shape, the plasma reactor 310 is easy to install in existing pipes. Preferably, the plasma reactor 310 includes a pipeline made of a dielectric material, such as insulating ceramic or quartz, and an electrode unit arranged on the outer or inner circumference of the pipeline.

Plasma possesses a sufficient energy atmosphere necessary for physicochemical reactions due to the presence of electrons, excited atoms or the like therein. As described above, unreacted precursor and process by-products are transferred along a vacuum line 340 from the process chambers and are decomposed in the plasma reactor 310. At this time, a metal precursor transferred along the vacuum line 340 is decomposed in the plasma reactor 310 to generate metal active species. Such metallic by-products may be coated in the vacuum exhaust system to form metal films. The metal films cause failure of the inner parts of the vacuum exhaust system. Specifically, the metal films may become causes of failure of a vacuum valve and may have a great influence on the operation of the vacuum pump, where the rotator-rotator clearance and rotator-housing clearance are at intervals of tens of micrometers.

According to one embodiment of the present invention, the vacuum exhaust system includes the supply unit 320 for supplying an oxidizing gas to the plasma reactor 310. The oxidizing gas contains an oxygen component. The oxidizing gas is preferably oxygen or ozone.

The metal active species present in the plasma react with the oxidizing gas to produce metal oxides. For example, tetrakis(ethylmethylamino) zirconium (TEMA-Zr) or Zr[N(CH₃)C₂H₅]₄) as a Zr precursor is activated and reacts with ozone in the plasma reactor 310 to produce ZrO₂. The metal precursor remaining unreacted is decomposed in the presence of the oxidizing gas to produce a metal oxide, and as a result, any metallic materials do not enter the vacuum exhaust system 300.

The oxidizing gas may be supplied to any position relative to the plasma reactor 310 so long as it has the ability to convert the residual metal precursor to a metal oxide. The oxidizing gas may be directly supplied to the plasma reactor 310, which is illustrated in FIG. 3. Alternatively, the oxidizing gas may be supplied upstream or downstream of the plasma reactor 310. When the oxidizing gas is supplied upstream of the plasma reactor 310, it can be advantageously pre-mixed with the process by-products. Meanwhile, when the oxidizing gas is supplied downstream of the plasma reactor 310, the oxidizing gas may be pretreated by energy supply so as to include oxygen active species.

A trap 350 may be installed downstream of the plasma reactor 310. The trap 350 may be installed upstream or downstream of the vacuum pump 330 and serves to remove the pollutants (e.g., process by-products) present in the exhaust gases by heating or cooling. By the installation of the trap 350, the amount of the pollutants directly entering the vacuum pump 330 can be further reduced. Unlike that illustrated in FIG. 3, the trap 350 may be installed downstream of the vacuum pump 330.

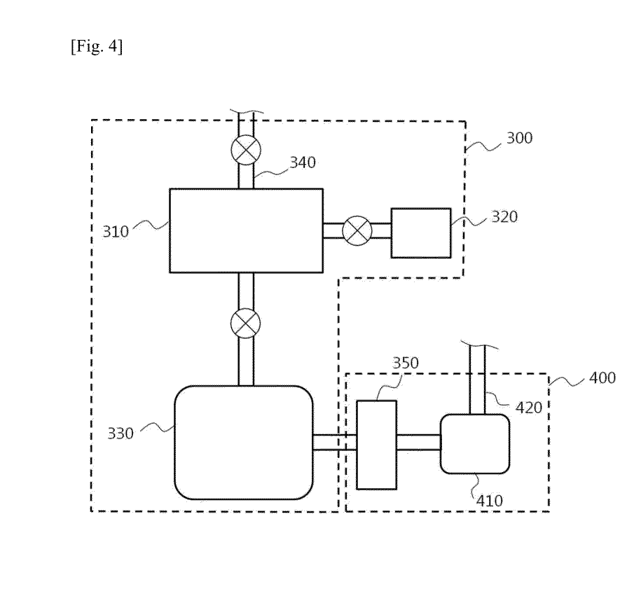

FIG. 4 is a block diagram illustrating the configuration of a vacuum system according to a further embodiment of the present invention. Referring to FIG. 4, the trap 350 is installed between the vacuum pump 330 and a scrubber 410. In this embodiment, the trap 350 may be reduced in size compared to when it is positioned upstream of the vacuum pump 330.

The vacuum pump 330 evacuates the process chambers of the process system 200 and releases exhaust gases generated in the process chambers into the atmosphere. The exhaust gases contain unreacted precursor and process by-products. In one embodiment, the vacuum exhaust system 300 may further include an auxiliary vacuum pump (not illustrated) upstream of the plasma reactor 310, i.e. between the process chambers (not illustrated) and the plasma reactor 310, in addition to the vacuum pump 330. The auxiliary vacuum pump prevents pressure variations caused by plasma generation from affecting the internal pressures of the process chambers while preventing the materials produced in the plasma reactor 310 from returning to the process chambers. Another role of the auxiliary vacuum pump is to increase the pumping speed of the vacuum pump 330.

The scrubber 410 of the exhaust system 400 functions to purify the exhaust gases and is connected between the vacuum pump 330 and an exhaust pipe 420.

In this embodiment, the use of the plasma reactor equipped with the oxidizing gas supply unit in the vacuum system for vacuum pumping can prevent metallic by-products derived from the metal precursor from directly entering the vacuum pump, as described above.

Unreacted raw materials including the unreacted metal precursor and process by-products are decomposed and converted into metal oxides by the oxidizing gas before entering the downstream parts, such as a vacuum pipe, a valve and the vacuum pump. The metal oxides are in the form of highly flowable powders. The metal oxides easily detached from the vacuum exhaust system although they are coated in the vacuum exhaust system to form metal oxide films, which is advantageous in extending the life of the vacuum exhaust system.

If a general hot trap is used for vacuum pumping system instead of the plasma reactor and the oxidizing gas, metallic solid by-products may enter the hot trap and the vacuum pump.

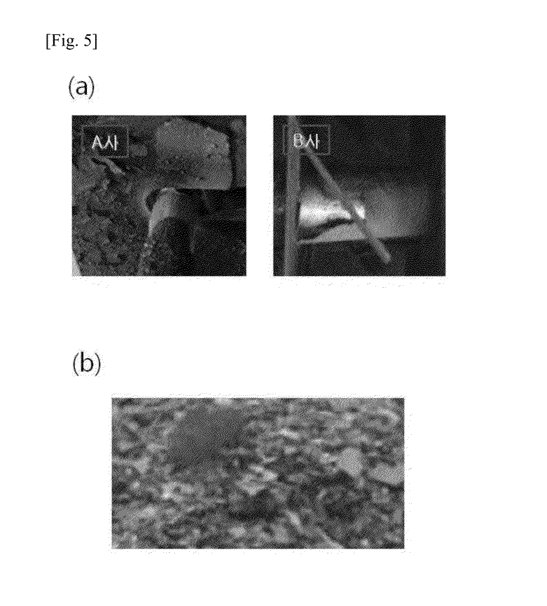

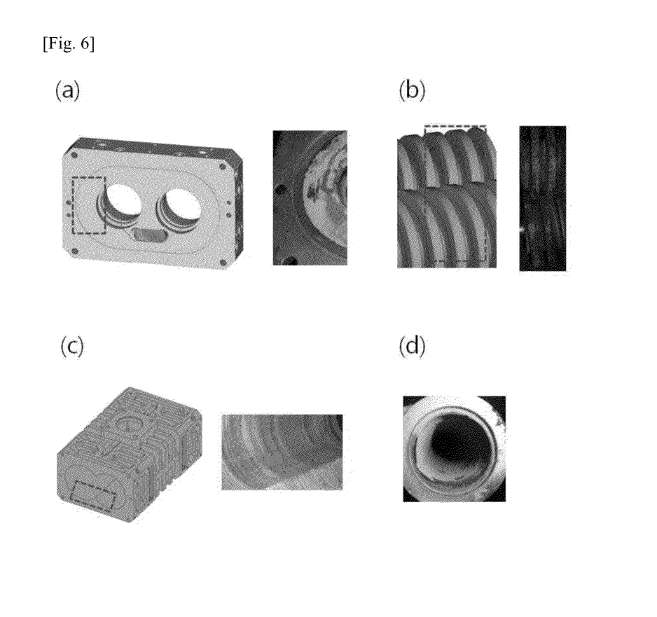

FIG. 5 shows photographs of hot trap baffles after residual metal precursors were captured with hot traps instead of the plasma reactor. In FIG. 5, (a) shows the use of hot trap products sold by two companies (Company A and Company B) and (b) shows solid by-products attached to a hot trap baffle. FIG. 6 shows photographs of a disassembled vacuum pump after the residual metal precursor was captured with a hot trap. In FIG. 6, (a), (b), (c), and (d) show a bearing plate, a rotor, a pump housing, and an exhaust pipe, respectively.

Referring to FIGS. 5 and 6, when the residual metal precursor was captured with the hot trap, the metallic solid by-products enter the hot trap baffles and the vacuum pump and are firmly attached to the inner surfaces of the components to form metal films, which negatively affect the vacuum exhaust system.

In contrast, according to one embodiment of the present invention, metal oxides are produced instead of the metallic solid by-products in the vacuum system including the plasma reactor and the oxidizing gas supply unit.

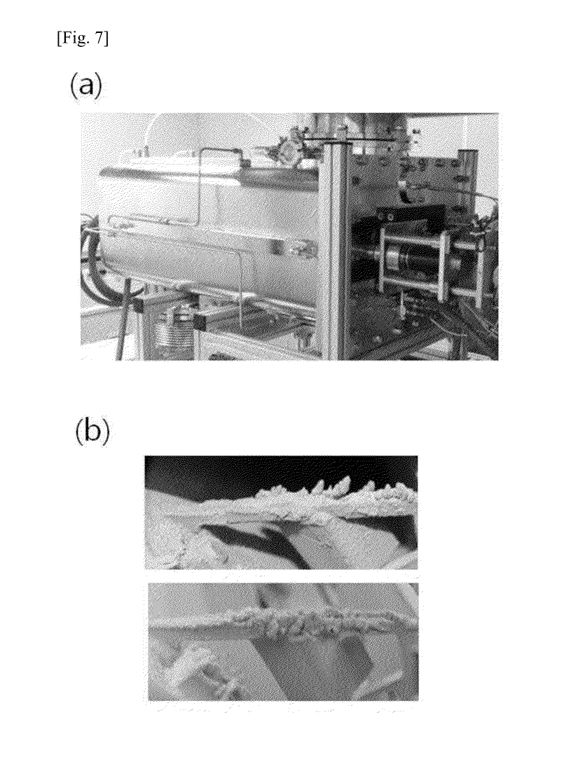

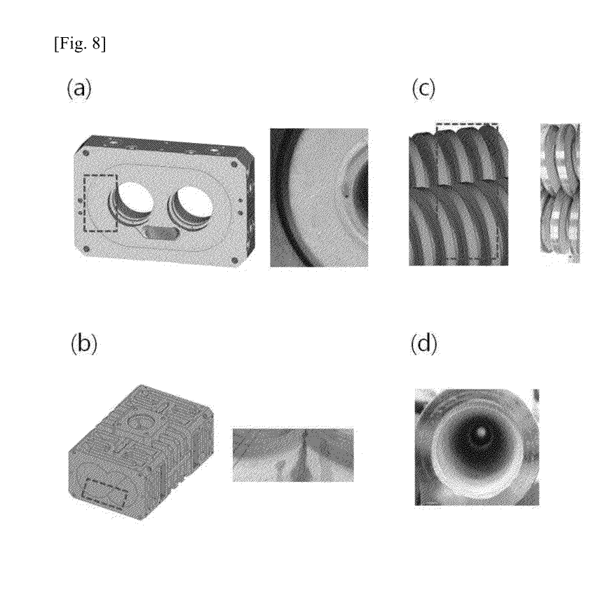

FIG. 7 shows (a) a photograph of a room temperature reaction trap and (b) photographs of trap baffles after oxygen was fed into the plasma reactor to convert the residual organic metal precursor to a metal oxide, which was then captured with the room temperature reaction trap. FIG. 8 shows the disassembled vacuum pump after the residual metal precursor was converted to a metal oxide, which was then captured with the room temperature reaction trap. In FIG. 8, (a), (b), (c), and (d) show a bearing plate, a rotor, a pump housing, and an exhaust pipe, respectively.

Referring to FIGS. 7 and 8, when the residual metal precursor was treated with plasma in the presence of oxygen, it is converted to a metal oxide in the form of a powder, which was captured by the trap baffles. At this time, a portion of the metal oxide powder entered the vacuum pump but was discharged to the exhaust pipe without being deposited in the vacuum pump due to its high flowability.

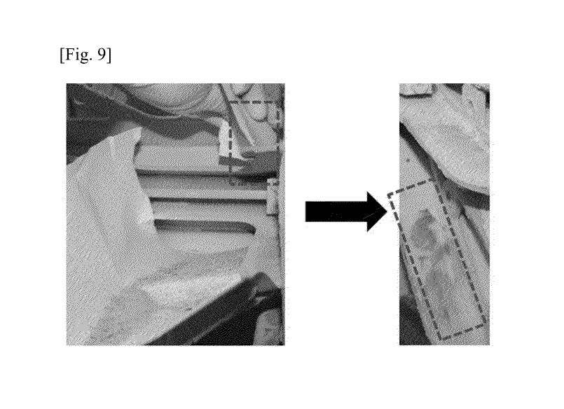

FIG. 9 shows photographs demonstrating the ease of removal of the metal oxide powder coated inside the vacuum exhaust system. Referring to FIG. 9, the metal oxide powder, which was produced from the residual metal precursor by plasma treatment in the presence of the oxidizing gas, did not form hard films like the metal films shown in FIGS. 5 and 6. Even when the powder was coated on the inner wall of the vacuum exhaust system, it could be scraped off with a simple cleaning tool, facilitating maintenance and repair of the trap. In conclusion, since the use of the vacuum system according to the embodiment of the present invention avoids the formation of difficult-to-detach metal films, the parts (e.g., vacuum valve, pipe, trap, and vacuum pump) of the vacuum system can be prevented from failure and the life of the vacuum system can be extended.

Although the present invention has been described in detail with reference to the drawings and embodiments, those skilled in the art will appreciate that various variations and modifications can be made to the embodiments without departing from the spirit of the present invention as disclosed in the appended claims.

1. A method for removing metallic by-products, comprising:
depositing a metal precursor to form a metal layer in a process chamber;
plasma treating an exhaust gas containing the residual metal precursor transferred from the process chamber;
treating metallic by-products generated by the plasma treatment with an oxidizing gas to produce metal oxides; and
discharging the metal oxides by pumping.

2. The method according to claim 1, wherein the metal precursor is selected from the group consisting of chlorides, hydroxides, oxyhydroxides, alkoxides, amides, nitrates, carbonates, acetates, oxalates, and citrates of at least one metal selected from the group consisting of Al, Cu, Ni, W, Zr, Ti, Si, Hf, La, Ta, and Mg or is a combination of these metal complexes.

3. The method according to claim 1, wherein the plasma is a dielectric barrier discharge created using an AC power supply.

4. The method according to claim 1, wherein the oxidizing gas is selected from the group consisting of air, oxygen, water vapor, ozone, nitrogen oxides, hydrogen peroxide, and alcohols.

5. The method according to claim 1, further comprising removing the metal oxides with a trap.

6. A vacuum system for removing metallic by-products, comprising:
a process chamber where a metal precursor as a raw material is received and deposited;
a vacuum pump for evacuating the process chamber and pumping an exhaust gas containing the metal precursor remaining unreacted in the process chamber;
a plasma reactor positioned between the process chamber and the vacuum pump to decompose the residual metal precursor; and
a supply unit for supplying an oxidizing gas to the plasma reactor to produce metal oxides.

7. The vacuum system according to claim 6, wherein the plasma reactor comprises a pipeline made of a dielectric material and an electrode unit arranged on the outer or inner circumference of the pipeline.

8. The vacuum system according to claim 6, wherein the supply unit supplies an oxygen-containing gas.

9. The vacuum system according to claim 6, further comprising a trap installed between the plasma reactor and the vacuum pump to capture the metal oxides.

10. The vacuum system according to claim 6, further comprising a scrubber installed downstream of the vacuum pump.

11. The vacuum system according to claim 10, further comprising a trap installed between the vacuum pump and the scrubber to capture the metal oxides.

12. The vacuum system according to claim 6, further comprising an auxiliary vacuum pump installed between the process chamber and the plasma reactor.
